(19) United States
(12) Patent Application Publication
(10) Pub. No.: US 2025/0176242 A1
(43) Pub. Date: May 29, 2025

(54) SEMICONDUCTOR DEVICE AND METHOD FOR FABRICATING THE SEMICONDUCTOR DEVICE

(71) Applicant: SK hynix Inc., Icheon-si Gyeonggi-do (KR)

(72) Inventors: Na Hye WON, Icheon-si Gyeonggi-do (KR); Sung Soo KIM, Icheon-si Gyeonggi-do (KR); Han Nae KIM, Icheon-si Gyeonggi-do (KR)

(73) Assignee: SK hynix Inc., Icheon-si Gyeonggi-do (KR)

(21) Appl. No.: 18/653,361

(22) Filed: May 2, 2024

(30) Foreign Application Priority Data
Nov. 28, 2023 (KR) 10-2023-0167826

(51) Int. Cl. H01L 29/66; H01L 21/265; H01L 21/306; H01L 29/08; H01L 29/40; H01L 29/417

(52) U.S. Cl. CPC H10D 64/021; H01L 21/26513; H01L 21/30604; H10D 62/151; H10D 64/01; H10D 64/254

(57) ABSTRACT

A semiconductor device includes: a gate structure including a gate dielectric layer, a gate electrode, and a gate capping layer that are sequentially stacked over a substrate; first spacers disposed on both sidewalls of the gate structure; a semiconductor layer disposed between the substrate and the gate structure and having both side surfaces that are aligned with outer surfaces of each first spacers; and second spacers disposed on side surfaces of the semiconductor layer and first spacers.

### CROSS-REFERENCE TO RELATED APPLICATIONS

The present application claims priority under 35 U.S.C 119(a) to Korean Patent Application No. 10-2023-0167826, filed on Nov. 28, 2023, in the Korean Intellectual Property Office, which application is incorporated herein by reference in its entirety.

### BACKGROUND

### 1. Technical Field

Various embodiments of the present disclosure generally relate to a method for fabricating a semiconductor device, and more particularly, to a semiconductor device including a gate of a peripheral circuit region, and a method for fabricating the semiconductor device.

### 2. Related Art

The demands for high integration and miniaturization of semiconductor devices require the size of semiconductor devices to become smaller and smaller. Also, semiconductor memory devices used in electronic devices require high integration, reducing design rules for the constituent elements of the semiconductor memory devices. Therefore, it is required to develop a technology that can improve device reliability while reducing the size of the devices.

### SUMMARY

In accordance with an embodiment, a semiconductor device includes: a gate structure including a gate dielectric layer, a gate electrode, and a gate capping layer that are sequentially stacked over a substrate; first spacers disposed on both sidewalls of the gate structure; a semiconductor layer disposed between the substrate and the gate structure and having both side surfaces that are aligned with outer surfaces of each first spacers; and second spacers disposed on side surfaces of the semiconductor layer and first spacers.

In accordance with an embodiment, a method for fabricating a semiconductor device includes: forming a semiconductor material layer over a substrate; forming a gate structure in which a gate dielectric layer, a gate electrode, and a gate capping layer are sequentially stacked over the semiconductor material layer; forming a first spacer material layer suitable for covering the semiconductor material layer and the gate structure; performing ion implantation process onto the semiconductor material layer; forming first spacers on both sidewalls of the gate structure by etching the first spacer material layer; forming a semiconductor layer that is aligned with outer surfaces of each first spacer by etching the semiconductor material layer; and forming second spacers over the semiconductor layer and the first spacers.

### BRIEF DESCRIPTION OF THE DRAWINGS

FIG. 1 is a cross-sectional view illustrating a semiconductor device in accordance with an embodiment.

FIGS. 2A, 2B, 2C, 2D, 2E, 2F, 2G, and 2H are cross-sectional views illustrating a process for fabricating a semiconductor device in accordance with an embodiment.

FIG. 3 is a cross-sectional view illustrating a semiconductor device in accordance with an embodiment.

### DETAILED DESCRIPTION

Embodiments will be described below in more detail with reference to the accompanying drawings. The embodiments may, however, be embodied in different forms and should not be construed as limited to the embodiments set forth herein. Throughout the disclosure, like reference numerals refer to like parts throughout the various figures and embodiments.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout.

Various embodiments are directed to a semiconductor device that can improve reliability of a device, and a method for fabricating the same.

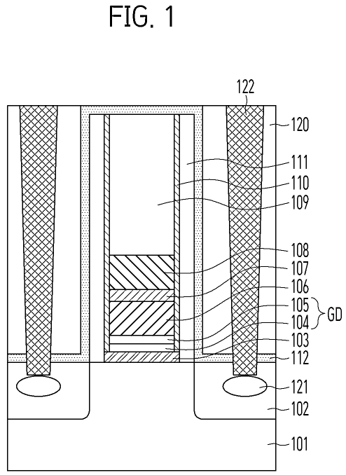

FIG. 1 is a cross-sectional view illustrating a semiconductor device in accordance with an embodiment.

Referring to FIG. 1, the semiconductor device may include a semiconductor layer 103 over a substrate 101, a gate structure, an inter-layer dielectric layer 120, and source/drain contacts 122.

The substrate 101 may include an active region and source/drain regions 102. The substrate 101 may include a peripheral circuit region. The substrate 101 may include a P-channel metal oxide semiconductor (PMOS) region of the peripheral circuit region.

In an embodiment, the substrate 101 may be a material appropriate for semiconductor processing. For example, the substrate 101 may include a semiconductor substrate. For example, the substrate 101 may be formed of a material containing silicon. For example, the substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. For example, the substrate 101 may include a semiconductor material, such as germanium. The substrate 101 may include a III/V-group semiconductor substrate, for example, a compound semiconductor substrate, such as GaAs. For example, the substrate 101 may include a silicon-on-insulator (SOI) substrate.

The semiconductor layer 103 may be partially disposed over the substrate 101. The semiconductor layer 103 may include, for example, silicon-germanium SiGe. In an embodiment, the Si—Ge bond may increase lattice spacing compared to the Si—Si bond, which increases the ion migration rate between a source and a drain, thereby improving the speed of the device. The line width of the semiconductor layer 103 may be adjusted to have at least the line width of the gate structure GS or more. The side surface of the semiconductor layer 103 may be aligned with the side surface of the first spacer 110. For example, as shown in FIG. 1, the semiconductor layer 103 may have both side surfaces aligned with the outer surfaces of each first spacer 110, respectively. For example, as shown in FIG. 1, a first end of the semiconductor layer 103 may align with the outer surface of a first spacer 110 whereby the first end does not protrude further than the outer surface of the first spacer 110. Additionally, for example, as shown in FIG. 1, a second end of the semiconductor layer 103, opposite the first end, may align with the other outer surface of the first spacer 110, whereby the second end does not protrude further than the outer surface of the other first spacer 110. In an embodiment, the distance between the semiconductor layer 103 and the source/drain contacts 122 may be equal to or greater than the sum of the thickness of the second spacer 111 and the thickness of the etch stop layer 112.

In an embodiment, each of the gate structures (i.e., 104 to 111) may include a gate dielectric layer GD, a gate electrode, a gate capping layer, and a gate spacer. In an embodiment, a single gate structure may include gate dielectric layer GD, a gate electrode (i.e., 106 to 108), and a gate capping layer 109. The gate dielectric layer GD may include a first dielectric layer 104 and a second dielectric layer 105 over the semiconductor layer 103. For example, the first dielectric layer 104 may include silicon oxide. For example, the second dielectric layer 105 may include a high-k layer. In an embodiment, the dielectric constant, k, is a parameter defining an ability of a material to store a charge. For example, the high-k layer may include a dielectric material with a higher dielectric constant than that of silicon oxide. For example, the second dielectric layer 105 may include one or more selected among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Each of the gate electrodes (i.e., 106 to 108) may include a stacked structure of a first conductive layer 106, a second conductive layer 107, and a third conductive layer 108. For example, a single gate electrode may include a stacked structure of a first conductive layer 106, a second conductive layer 107, and a third conductive layer 108. In an embodiment, a work function adjustment layer may be further included between the first conductive layer 106 and the gate dielectric layer GD. For example, the work function adjustment layer may include a metal, a conductive metal nitride, a conductive metal carbide, a conductor containing metal atoms, or a combination thereof. For example, the work function adjustment layer may include titanium nitride.

The first to third conductive layers 106, 107, and 108 may include at least one selected among metals, metal alloys, conductive metal nitrides, metal silicides, doped semiconductor materials, conductive metal oxides, conductive metal oxynitrides, and combinations thereof.

For example, the first conductive layer 106 may include doped polysilicon. In an embodiment, the second conductive layer 107 and the third conductive layer 108 may include a combination of a metal and a metal nitride. In an embodiment, the second conductive layer 107 may include a stacked structure of metal-based materials as a barrier metal. For example, the second conductive layer 107 may include a stacked structure of titanium, tungsten nitride, and tungsten silicon nitride. For example, the third conductive layer 108 may include tungsten.

In an embodiment, the gate capping layer 109 may be provided for protecting the upper surface of the third conductive layer 108 and patterning the gate dielectric layer GD and the first to third conductive layers 106, 107 and 108. In an embodiment, the gate capping layer 109 may be formed of a material having an etch selectivity with respect to the gate dielectric layer GD and the first to third conductive layers 106, 107 and 108. For example, the gate capping layer 109 may include silicon nitride.

First spacers 110 may be disposed on both sidewalls of the gate electrodes 106 to 108 and the gate capping layer 109. For example, as shown in FIG. 1, first spacers 110 may be disposed on opposing sidewalls of the gate structure (i.e., gate dielectric layer GD, a gate electrode (i.e., 106 to 108), and a gate capping layer 109), respectively. Both side surfaces of a first spacer 110 may be aligned with both side surfaces of the semiconductor layer 103, respectively. The upper surfaces of the first spacers 110 may be disposed at the same level as the upper surface of the gate capping layer 109. The bottom surfaces of the first spacers 110 may be disposed at a higher level than the upper surface of the substrate 101. The bottom surfaces of the first spacers 110 may contact the upper surface of the semiconductor layer 103. The second spacer 111 may be disposed over the first spacer 110. For example, the first spacer 110 may include silicon nitride. In an embodiment, the second spacers 111 may respectively be disposed on side surfaces of the semiconductor layer 103 and the first spacers 110 as shown in FIG. 1. For example, as shown in FIG. 1, a second spacer 111 may be disposed on a first side surface of the semiconductor layer 103 and a side surface of a first spacer 110 aligned with the first side surface of the semiconductor layer 103, and another second spacer 111 may be disposed on a second side surface of semiconductor layer 103 opposite the first side surface and a side surface of the other first spacer 110 aligned with the second side surface of the semiconductor layer 103. The second spacer 111 may include a material having an etch selectivity with respect to the first spacers 110. In an embodiment, the second spacer 111 may have a thickness which is greater than the thickness of the first spacer 110. In an embodiment, the upper surface of the second spacer 111 may be disposed at the same level as the upper surface of the gate capping layer 109. In an embodiment, the bottom surface of the second spacer 111 may be disposed at a lower level than the bottom surface of the first spacer 110. In an embodiment, the bottom surface of the second spacer 111 may contact the upper surface of the substrate 101. For example, the second spacer 111 may include silicon oxide.

An etch stop layer 112 covering the gate capping layer 109 and the second spacer 110 may be disposed over the substrate 101. The etch stop layer 112 may include a material having an etch selectivity with respect to the substrate 101. The etch stop layer 112 may include a material having an etch selectivity with respect to the second spacer 111 and the inter-layer dielectric layer 120. For example, the etch stop layer 112 may include silicon nitride.

The inter-layer dielectric layer 120 may be disposed over the etch stop layer 112. For example, the inter-layer dielectric layer 120 may include one selected among silicon oxide, silicon nitride, and silicon oxynitride.

The source and drain (source/drain) regions 102 may be formed in the substrate 101. Each of the gate structures may be disposed between the source and drain regions 102. The source/drain regions 102 may include impurities implanted into a portion of the substrate 101. The source/drain regions 102 may further include an additional ion implantation region 121. In an embodiment, the additional ion implantation region 121 may contain additional impurities to reduce the contact resistance of the source/drain contacts 122 and to increase device characteristics. For example, the additional ion implantation region 121 may include germanium and boron.

The source/drain contacts 122 may be electrically connected to the source/drain regions 102. In an embodiment, the source/drain contacts 122 may vertically penetrate the inter-layer dielectric layer 120 and the etch stop layer 112 and contact the source/drain regions 102. According to an embodiment, a metal silicide may be further included between the source/drain contacts 122 and the substrate 101.

In an embodiment, the source/drain contacts 122 may include a metal or a metal nitride. For example, the source/drain contacts 122 may include one selected among metals, such as titanium, tungsten, nickel and cobalt, metal nitrides, such as titanium nitride, titanium silicon nitride, titanium aluminum nitride, tantalum nitride, tantalum silicon nitride, and tungsten nitride, and combinations thereof. According to an embodiment, the source/drain contacts 122 may include a stacked structure of a barrier metal and a metal material. For example, the barrier metal may include a stacked structure of titanium nitride, titanium, and cobalt, and the metal material may include tungsten.

As described above, according to an embodiment, as the side surface of the semiconductor layer 103 is formed to be aligned with the side surface of the first spacer 110, the distance between the semiconductor layer 103 and the source/drain contacts 122 may be secured. In other words, in an embodiment, contact failure between the semiconductor layer 103 and the source/drain contacts 122 may be prevented or mitigated. Therefore, in an embodiment, it is possible to prevent or mitigate GIDL characteristic deterioration that may be caused by metal penetration and growth in the source/drain contacts 122 through the semiconductor layer 103.

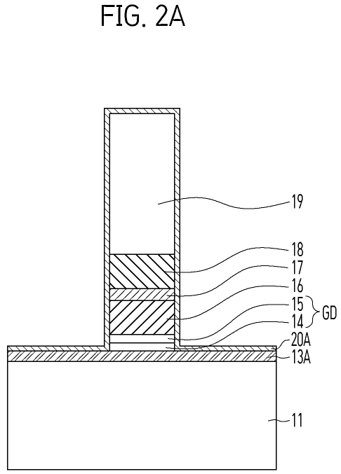

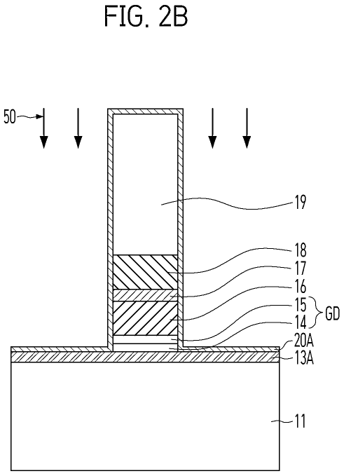

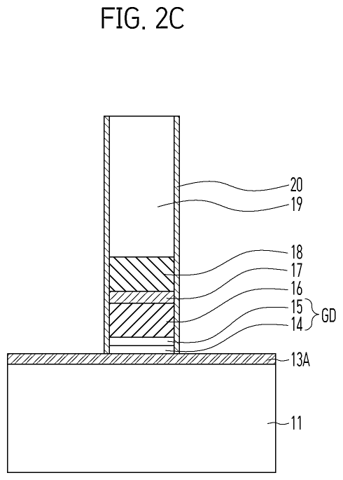

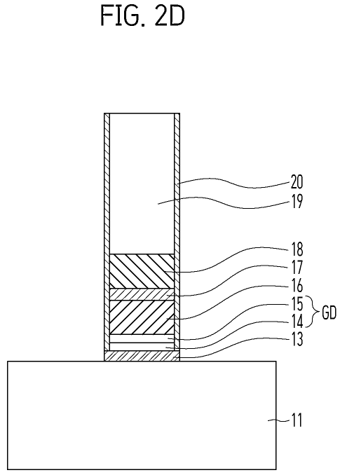

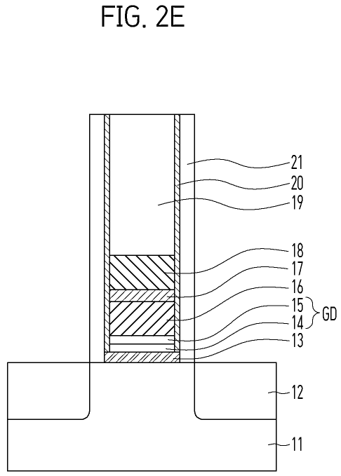

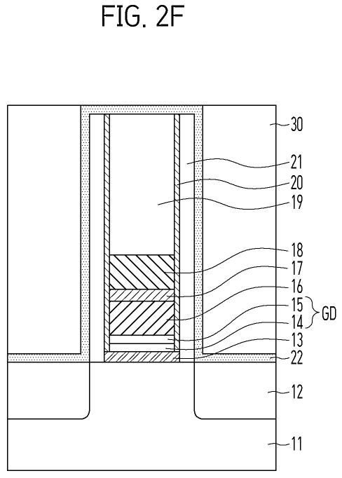

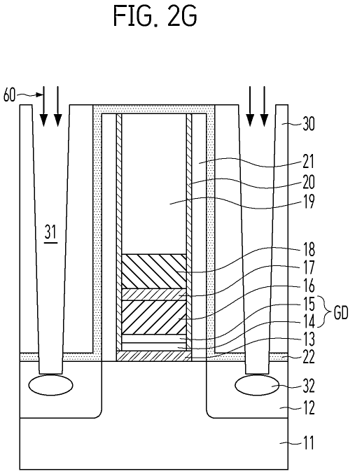

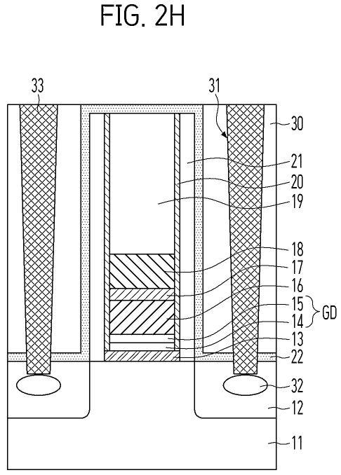

FIGS. 2A to 2H are cross-sectional views illustrating a process for fabricating a semiconductor device in accordance with an embodiment.

Referring to FIG. 2A, a semiconductor material layer 13A may be formed over a substrate 11. The substrate 11 may include an active region. In an embodiment, the substrate 11 may be a material appropriate for semiconductor processing. For example, the substrate 11 may include a semiconductor substrate. For example, the substrate 11 may be formed of a material containing silicon. For example, the substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. In an embodiment, the substrate 11 may include a semiconductor material, such as germanium. The substrate 11 may include a III/V-group semiconductor substrate, for example, a compound semiconductor substrate, such as GaAs. In an embodiment, the substrate 11 may include a silicon-on-insulator (SOI) substrate. The substrate 11 may have different conductivity types according to an NMOS transistor region or a PMOS transistor region.

Subsequently, a semiconductor material layer 13A may be formed over the substrate 11. In an embodiment, the semiconductor material layer 13A may contain a material that may improve carrier mobility. For example, the semiconductor material layer 13A may be a silicon germanium (SiGe) layer.

Subsequently, each of the gate structures (i.e., 14 to 21) may be formed over the semiconductor material layer 13A. In an embodiment, a single gate structure may include a gate dielectric layer GD, a gate electrode, a gate capping layer, and a gate spacer. In an embodiment, a single gate structure may include gate dielectric layer GD, a gate electrode (i.e., 16 to 18), and a gate capping layer 19. The gate dielectric layer GD may include a first dielectric layer 14 and a second dielectric layer 15 over the semiconductor material layer 13A. For example, the first dielectric layer 14 may include silicon oxide. In an embodiment, the second dielectric layer 15 may include a high-k layer. For example, the high-k layer may include a dielectric material which is higher than silicon oxide. For example, the second dielectric layer 15 may include one or more selected among boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Each of the gate electrodes (i.e., 16 to 18) may include a stacked structure of a first conductive layer 16, a second conductive layer 17, and a third conductive layer 18. For example, a single gate electrode may include a stacked structure of a first conductive layer 16, a second conductive layer 17, and a third conductive layer 18. In an embodiment, a work function adjustment layer may be further included between the first conductive layer 16 and the gate dielectric layer GD. The work function adjustment layer may include a metal, a conductive metal nitride, a conductive metal carbide, a conductor containing metal atoms, or a combination thereof. For example, the work function adjustment layer may include titanium nitride.

The first to third conductive layers 16, 17 and 18 may include at least one selected among metals, metal alloys, conductive metal nitrides, metal silicides, doped semiconductor materials, conductive metal oxides, conductive metal oxynitrides, and combinations thereof.

For example, the first conductive layer 16 may include doped polysilicon. For example, the second conductive layer 17 and the third conductive layer 18 may include a combination of a metal and a metal nitride. In an embodiment, the second conductive layer 17 may include a stacked structure of metal-based materials as a barrier metal. For example, the second conductive layer 17 may include a stacked structure of titanium, tungsten nitride, and tungsten silicon nitride. For example, the third conductive layer 18 may include tungsten.

In an embodiment, the gate capping layer 19 may be provided for protecting the upper surface of the third conductive layer 18 and patterning the gate dielectric layer GD and the first to third conductive layers 16, 17 and 18. In an embodiment, the gate capping layer 19 may be formed of a material having an etch selectivity with respect to the gate dielectric layer GD and the first to third conductive layers 16, 17 and 18. For example, it may include silicon nitride.

Subsequently, a first spacer material layer 20A covering the semiconductor material layer 13A and the gate structure may be formed. The first spacer material layer 20A may be formed conformally on the profile of the surfaces of the semiconductor material layer 13A and the gate structure. For example, the first spacer material layer 20A may include silicon nitride.

Referring to FIG. 2B, an ion implantation process 50 may be performed onto the semiconductor material layer 13A. The ion implantation process 50 may be performed to increase the selectivity during a subsequent wet etching process. The ion implantation process 50 may be performed using a germanium material. According to an embodiment, the ion implantation energy may be controlled to be lower than when targeting the substrate 11 such that the ion implantation process 50 may be performed only onto the semiconductor material layer 13A.

Although not illustrated, in an embodiment, the ion implantation process for forming an lightly-doped drain (LDD) region in the substrate 11 may be further performed before the ion implantation process 50 is performed.

Referring to FIG. 2C, first spacers 20 may be formed on both sidewalls of the gate structure. To this end, the first spacer material layer 20A (see FIG. 2B) may be dry etched. As a result, the first spacer material layer 20A (see FIG. 2B) over the gate capping layer 19 and the semiconductor material layer 13A may be removed, and the first spacers 20 may be formed on both sidewalls of the gate dielectric layer GD, the gate electrode, and the gate capping layer 19, respectively. For example, as shown in FIG. 2C, first spacers 20 may be disposed on opposing sidewalls of the gate structure (i.e., gate dielectric layer GD, a gate electrode (i.e., 16 to 18), and a gate capping layer 19), respectively.

Referring to FIG. 2D, the semiconductor layer 13 may be formed. The semiconductor layer 13 may be disposed only between the gate structure and the substrate 11. The side surfaces of the semiconductor layer 13 may be aligned with the sidewalls of the first spacers 20. To this end, in an embodiment, a wet etching process may be performed onto the semiconductor material layer 13A (see FIG. 2C) to form the semiconductor layer 13. The wet etching process may include a cleaning process after the dry etching process of FIG. 2C. The wet etching process may be performed under the condition of having an etch selectivity with respect to the substrate 11. In other words, the wet etching process may be performed under the condition of selectively removing the residue and the semiconductor material layer 13A (see FIG. 2C) after the dry etching process of FIG. 2C. For example, the wet etching process may be performed using an etchant, such as a sulfuric acid peroxide mixture (SPM), peracetic acid (PAA) (CH₃COOH and H₂O₂), and hydrofluoric acid (HF).

By separately performing a dry etching process for forming the first spacers 20 and a wet etching process for forming the semiconductor layer 13, the loss of the substrate 11 may be minimized. Also, in FIG. 2B, the loss of the substrate 11 may be minimized without leaving etching by-products or the semiconductor material layer 13A (see FIG. 2C) by additionally ion-implanting germanium into the semiconductor material layer 13A to increase the etching selectivity.

Referring to FIG. 2E, the second spacer 21 may be formed on the side surfaces of the semiconductor layer 13 and the first spacer 20. In an embodiment, the second spacer 21 may have a thickness which is greater than that of the first spacers 20. For example, the second spacer 21 may include silicon oxide.

Subsequently, source/drain regions 12 may be formed in the substrate 11 on both side surfaces of the gate structure.

Referring to FIG. 2F, an etch stop layer 22 may be formed on the profile of the substrate 11 and the second spacer 21. In an embodiment, the etch stop layer 22 may serve as a third spacer of the gate structure and at the same time serve as an etch stop when contact holes for source/drain contacts are formed subsequently. In an embodiment, the etch stop layer 22 may be formed conformally on the profile of the substrate 11 and the second spacer 21. In an embodiment, the etch stop layer 22 may have a thickness which is smaller than the thickness of the second spacer 21. The etch stop layer 22 may include a material having an etch selectivity with respect to the substrate 11 and the second spacer 21. For example, the etch stop layer 22 may include silicon nitride.

Subsequently, an inter-layer dielectric layer 30 may be formed over the etch stop layer 22. The inter-layer dielectric layer 30 may be formed through a process of forming a dielectric material over the etch stop layer 22 and performing a planarization process targeting the etch stop layer 22 over the gate structure to be exposed. For example, the inter-layer dielectric layer 30 may include silicon oxide.

Referring to FIG. 2G, a contact hole 31 that exposes the source/drain regions 12 may be formed through the inter-layer dielectric layer 30 and the etch stop layer 22. The etching process for forming the contact hole 31 may be divided into a process of etching the inter-layer dielectric layer 30 and a process of etching the etch stop layer 22.

Subsequently, an additional ion implantation process 60 may be performed. As a result, an additional ion implantation region 32 may be formed in the source/drain regions 12. For example, the additional ion implantation process 60 may be performed using germanium and boron.

Referring to FIG. 2H, the source/drain contacts 33 may be formed by gap-filling the contact hole 31 with a conductive material. The source/drain contacts 33 may include a metal or a metal nitride. For example, the source/drain contacts 33 may include one selected among metals, such as titanium, tungsten, nickel, and cobalt, and metal nitrides, such as titanium nitride, titanium silicon nitride, titanium aluminum nitride, tantalum nitride, tantalum silicon nitride, and tungsten nitride, and combinations thereof. According to an embodiment, the source/drain contacts 33 may include a stacked structure of a barrier metal and a metal material. For example, the barrier metal may include a stacked structure of titanium nitride, titanium, and cobalt, and the metal material may include tungsten.

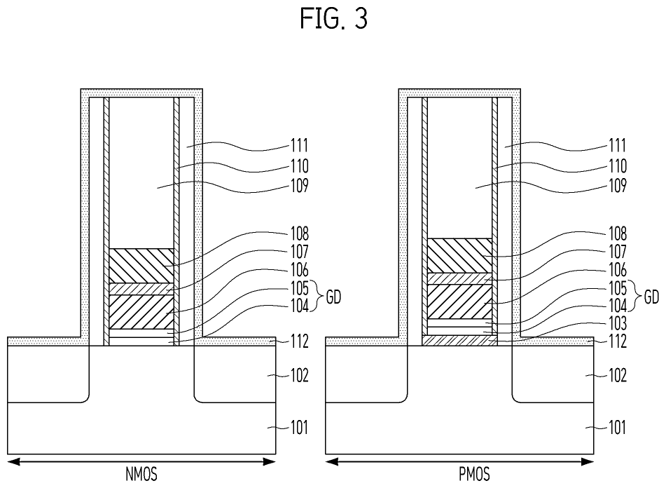

FIG. 3 is a cross-sectional view illustrating a semiconductor device in accordance with an embodiment. The reference numbers of FIG. 3 corresponding the reference numbers shown in FIG. 1 may represent the same constituent elements.

Referring to FIG. 3, the substrate 101 may include an active region and source/drain regions 102. The substrate 101 may include a peripheral circuit region. The substrate 101 may include an N-channel metal-oxide semiconductor (NMOS) region and a PMOS region in the peripheral circuit region.

A transistor in the PMOS region may include the same structure as the transistor illustrated in FIG. 1.

In an embodiment, a transistor in the NMOS region may include the same structure as the transistor illustrated in FIG. 1, except for the semiconductor layer 103. In an embodiment, the transistor in the NMOS region may have a thickness which is smaller than that of the transistor in the PMOS region by the thickness of the semiconductor layer 103.

In an embodiment, the bottom surface of the first spacer 110 of the transistor in the NMOS region may contact the substrate 101 as shown in FIG. 3.

According to an embodiment, the separation distance between a gate channel and a contact may be secured.

According to an embodiment, it is possible to prevent or mitigate defects that may be caused by metal diffusion into the contact through the gate channel.

While the embodiments have been described with respect to the specific embodiments, it will be apparent to those skilled in the art that various changes and modifications may be made without departing from the spirit and scope of the disclosure as defined in the following claims.

What is claimed is:

1. A semiconductor device, comprising:
a gate structure comprising a gate dielectric layer, a gate electrode, and a gate capping layer that are sequentially stacked over a substrate;
first spacers disposed on opposing sidewalls of the gate structure, respectively;
a semiconductor layer disposed between the substrate and the gate structure and having both side surfaces aligned with outer surfaces of each first spacer, respectively; and
second spacers respectively disposed on side surfaces of the semiconductor layer and the first spacers.

2. The semiconductor device of claim 1, wherein bottom surfaces of the first spacers each contact the semiconductor layer.

3. The semiconductor device of claim 1, wherein bottom surfaces of the second spacers each contact the substrate.

4. The semiconductor device of claim 1, wherein the semiconductor layer comprises silicon germanium.

5. The semiconductor device of claim 1, wherein a thickness of each second spacer is greater than a thickness of each first spacer.

6. The semiconductor device of claim 1, wherein the gate dielectric layer includes a stacked structure of silicon oxide and a high-k layer.

7. The semiconductor device of claim 1, further comprising:
source and drain (source/drain) regions disposed in the substrate, and the gate structure disposed between the source/drain regions.

8. The semiconductor device of claim 1, further comprising:
an etch stop layer suitable for covering the gate structure and the substrate;
an inter-layer dielectric layer disposed over the etch stop layer; and
source/drain contacts suitable for penetrating the inter-layer dielectric layer and the etch stop layer and contacting the substrate.

9. The semiconductor device of claim 1, wherein a width of the semiconductor layer is at least equal to or greater than a width of the gate structure.

10. A method for fabricating a semiconductor device, comprising:
forming a semiconductor material layer over a substrate;
forming a gate structure in which a gate dielectric layer, a gate electrode, and a gate capping layer are sequentially stacked over the semiconductor material layer;
forming a first spacer material layer suitable for covering the semiconductor material layer and the gate structure;
performing ion implantation process onto the semiconductor material layer;
forming first spacers on opposing sidewalls of the gate structure, respectively, by etching the first spacer material layer;
forming a semiconductor layer aligned with outer surfaces of each first spacer, respectively, by etching the semiconductor material layer; and
forming second spacers over side surfaces of the semiconductor layer and the first spacers.

11. The method of claim 10, wherein the performing of the ion implantation process comprises using germanium.

12. The method of claim 10, wherein the forming of the first spacers on opposing sidewalls of the gate structure, respectively, by etching the first spacer material layer comprises using a dry etching process.

13. The method of claim 10, wherein the forming of the semiconductor layer aligned with outer surfaces of each first spacer, respectively, by etching the semiconductor material layer comprises using a wet etching process.

14. The method of claim 10, wherein the wet etching process comprises using one etchant selected among a sulfuric acid peroxide mixture (SPM), peracetic acid (PAA), and hydrofluoric acid (HF).

15. The method of claim 10, wherein the first spacers comprise a material having an etch selectivity with respect to the semiconductor layer.

16. The method of claim 10, wherein the semiconductor layer comprises silicon germanium.

17. The method of claim 10, wherein the first spacers comprise silicon nitride.

18. The method of claim 10, wherein the second spacer comprises a material having an etch selectivity with respect to the first spacers.

19. The method of claim 10, wherein the second spacer comprises silicon oxide.
